(19) United States
(12) Patent Application Publication
(10) Pub. No.: US 2016/0223598 A1
(43) Pub. Date: Aug. 4, 2016

(54) COMPUTING METHOD AND COMPUTING DEVICE

(71) Applicant: FUJITSU LIMITED, Kawasaki-shi (JP)

(72) Inventors: Kai Nojima, Yokohama (JP); Shogo Fujimori, Yamato (JP); Kenji NAGASE, Yokohama (JP); Hirotomo Izumi, Kawasaki (JP)

(73) Assignee: FUJITSU LIMITED, Kawasaki-shi (JP)

(21) Appl. No.: 14/956,757

(22) Filed: Dec. 2, 2015

(30) Foreign Application Priority Data
Jan. 29, 2015 (JP) 2015-016015

(51) Int. Cl. G01R 19/10; G01R 19/00

(52) U.S. Cl. CPC G01R 19/10; G01R 19/0092

(57) ABSTRACT

A computing method includes: detecting, in a circuit board, a coordinate of an area where a current greater than or equal to a threshold flows; extracting signal layer currents and GND layer currents within a given range based on the coordinate, the signal layer currents flowing in a signal layer and the GND layer currents flowing in a GND layer; computing, by a computer, a first current as a sum of the signal layer currents and a second current as a sum of the GND layer currents; and computing a third current as a sum of the first current and the second current in a section direction of the circuit board.

### CROSS-REFERENCE TO RELATED APPLICATION

This application is based upon and claims the benefit of priority of the prior Japanese Patent Application No. 2015-016015, filed on Jan. 29, 2015, the entire contents of which are incorporated herein by reference.

### FIELD

The embodiments discussed herein are related to a computing method and a computing device.

### BACKGROUND

Noise sources that produce radiation noise have been identified in printed circuit boards for use in electric appliances or the like.

Related art is disclosed in Japanese Laid-open Patent Publication No. 2009-123068 or Japanese Laid-open Patent Publication No. 2009-3790.

### SUMMARY

According to an aspect of the embodiments, a computing method includes: detecting, in a circuit board, a coordinate of an area where a current greater than or equal to a threshold flows; extracting signal layer currents and GND layer currents within a given range based on the coordinate, the signal layer currents flowing in a signal layer and the GND layer currents flowing in a GND layer; computing, by a computer, a first current as a sum of the signal layer currents and a second current as a sum of the GND layer currents; and computing a third current as a sum of the first current and the second current in a section direction of the circuit board.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an example of a functional configuration of a computing device;

FIG. 2A to FIG. 2C depict an example of data of current information;

FIG. 3 illustrates an example of a combined range;

FIG. 4 illustrates an example of a combined range;

FIG. 5 illustrates an example of a combined range;

FIG. 6 depicts an example of data of combined range information;

FIG. 7 illustrates an example of a detection process;

FIG. 8 illustrates an example of an extraction process;

FIG. 9 illustrates an example of a first computing process;

FIG. 10 illustrates an example of a second computing process;

FIG. 11 illustrates an example of combined currents in a match pattern;

FIG. 12 illustrates an example of a combined current at a circuit board end;

FIG. 13 illustrates an example of a combined current when there is a relatively short slit;

FIG. 14 illustrates an example of a combined current when there is a relatively long slit;

FIG. 15 illustrates an example of a combined current in a guard pattern case;

FIG. 16A to FIG. 16C illustrate an example of distribution of current values in a match pattern case;

FIG. 17A to FIG. 17C illustrate an example of distribution of current values when there is a slit;

FIG. 18A to FIG. 18C illustrate an example of distribution of current values when a common mode current flows;

FIG. 19 illustrates an example of an anti-noise measures process;

FIG. 20 illustrates an example of a computing process;

FIG. 21A to FIG. 21C illustrate an example of distribution of current values expressed in vectors; and

FIG. 22 illustrates an example of a computer.

### DESCRIPTION OF EMBODIMENTS

For example, an area where a current in a near electromagnetic field measured through an electromagnetic field simulation is large is considered to be a noise source, and thus the noise source may be identified.

It may be difficult to identify a noise source. For example, in a printed circuit board, when a current flows through a wiring line, a return current might occur. For example, if such a return current flows sufficiently close to a signal wiring line, radio waves cancel each other out and therefore the radiation level, which indicates the intensity of radiation, at a distant observation point is low. For example, if a return current flows on the ground or the like apart from the signal wiring line, radio waves do not cancel each other out and therefore the radiation level is high. For this reason, owing to the effect of a return current, an area where the current in a near electromagnetic field is large may not be a noise source for which there is a higher priority for measures to be taken. Therefore, according to the methods mentioned above, a noise source may not be identified.

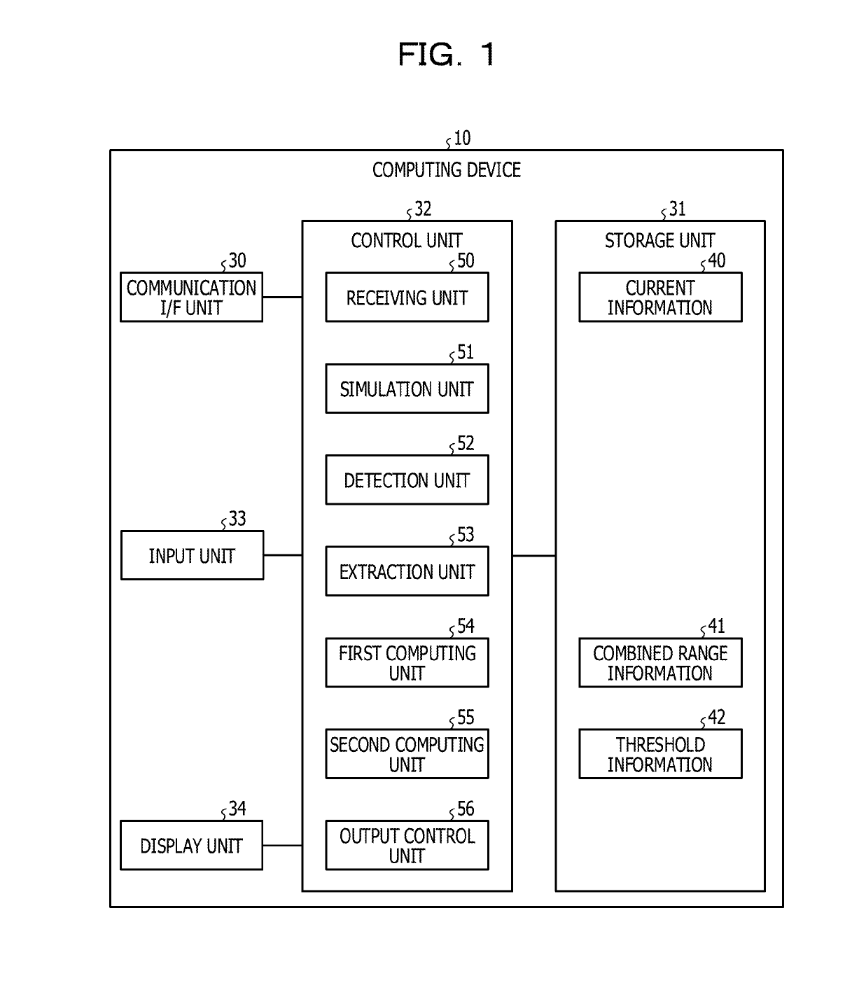

FIG. 1 illustrates an example of a functional configuration of a computing device. A computing device 10 may be a device that carries out a simulation for identifying a noise source, which is a source at which radiation noise radiated from the circuit board is produced. For example, the computing device 10 may compute, through a simulation, a combined current as a sum of a current in a signal layer and a current in a GND layer of the circuit board in the section direction and, based on the computed combined current, may display noise source distribution. As illustrated in FIG. 1, the computing device 10 includes a communication interface (I/F) unit 30, a storage unit 31, a control unit 32, an input unit 33, and a display unit 34.

The communication I/F unit 30 is an interface that controls communication with other devices. The communication I/F unit 30 transmits and receives various kinds of information via a network with other devices. For example, the communication I/F unit 30 receives information related to combined range information 41 and threshold information 42 from other devices. As the communication I/F unit 30, a network interface card such as a local area network (LAN) card may be employed. The computing device 10 may obtain information such as the information related to the combined range information 41 and the threshold information 42 via a recording medium such as a memory card. The information related to the combined range information 41 and the threshold information 42 may be input from the input unit 33.

The storage unit 31 may be a storage device, such as a semiconductor memory element such as a flash memory, a hard disk, or an optical disk. The storage unit 31 may be a data-rewritable semiconductor memory, such as a random access memory (RAM), a flash memory, or a non-volatile static random access memory (NVSRAM).

The storage unit 31 stores an operating system (OS) executed on the control unit 32 and various programs for processing received requests. The storage unit 31 stores various kinds of data used for programs executed on the control unit 32. For example, the storage unit 31 stores current information 40, the combined range information 41, and the threshold information 42.

The current information 40 may be data on a current on the circuit board obtained through an electromagnetic field simulation run by the simulation unit 51. For example, in the current information 40, coordinates representing positions on the circuit board and current values are stored in association with each other for each of the signal layer and the GND layer.

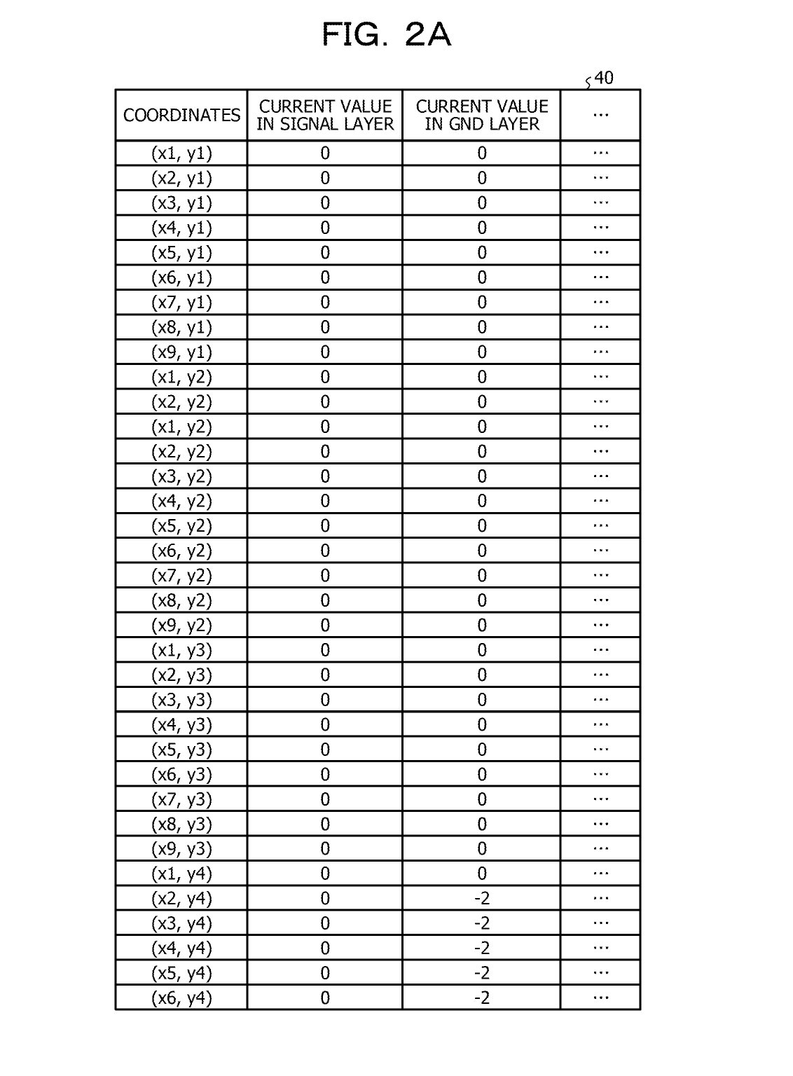

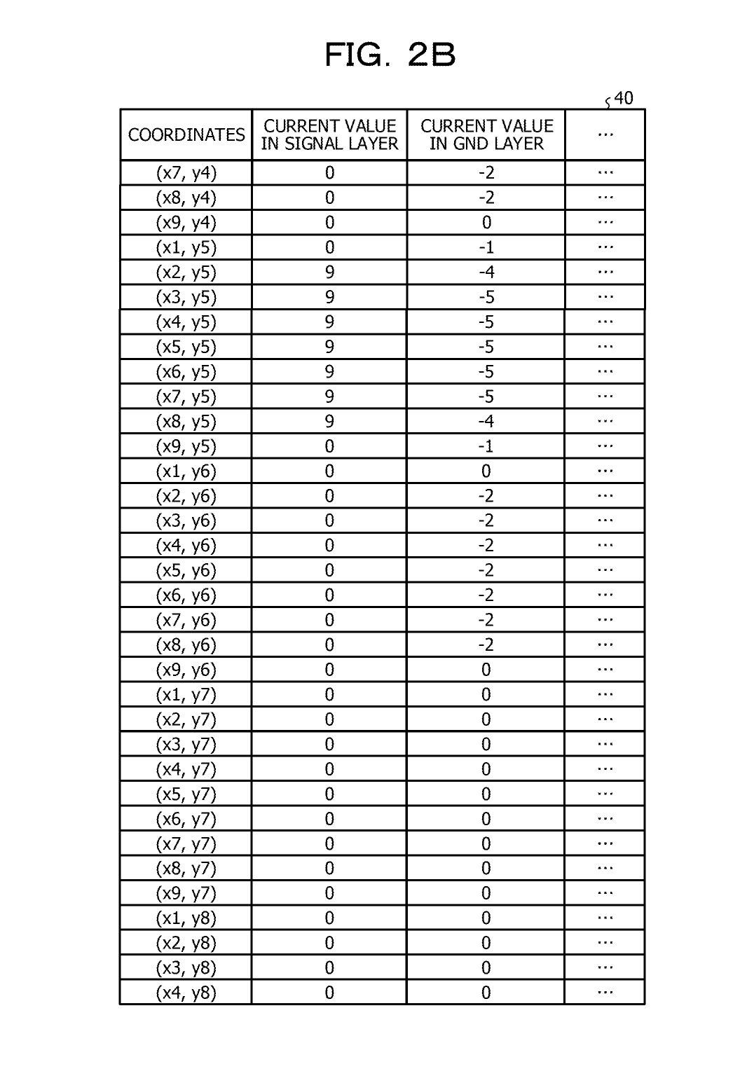

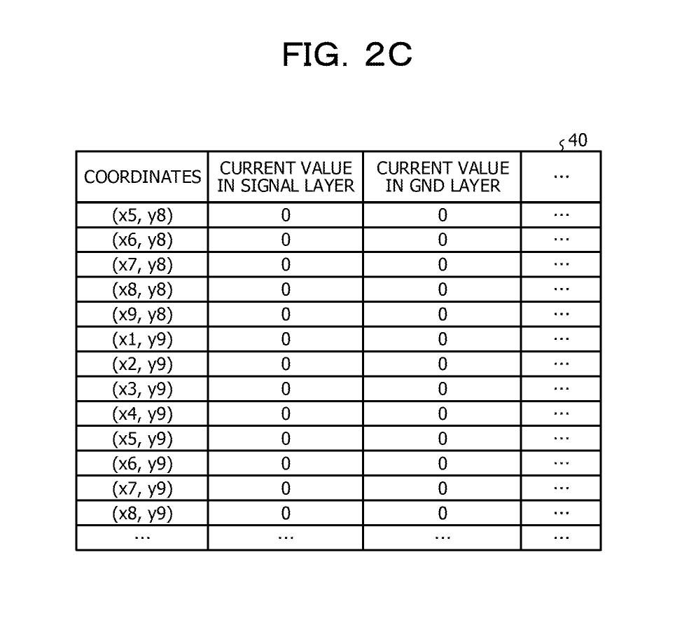

FIG. 2A to FIG. 2C illustrate an example of data of current information. The current information 40 may be a table in which items of coordinates, a current value in the signal layer, a current value in the GND layer, and so on are associated with one another. The item of coordinates is an area storing coordinates representing positions on the circuit board. For example, in the item of coordinates, a combination of an X coordinate and a y coordinate representing a position on the circuit board is stored. The item of a current value in the signal layer is an area storing the current values of a current flowing in the signal layer among currents measured through an electromagnetic field simulation. For example, in the item of a current value in the signal layer, the current value of a current flowing in the signal layer at a position on the circuit board corresponding to coordinates is stored. The item of a current value in the GND layer is an area storing the current values of a current flowing in the GND layer among currents measured through the electromagnetic field simulation. For example, in the item of a current value in the GND layer, the current value of a current flowing in the GND layer at a position on the circuit board corresponding to coordinates is stored.

In FIG. 2A to FIG. 2C, the current value in the signal layer is indicated as “9” at positions of coordinates (x2, y5) to (x8, y5). The current value in the signal layer is indicated as “0” at positions other than those of the coordinates (x2, y5) to (x8, y5). As a result, in the signal layer, a strong current flows at the positions of the coordinates (x2, y5) to (x8, y5) compared to the positions of other coordinates.

The current value in the GND layer is indicated as “−2” at positions of coordinates (x2, y4) to (x8, y4). The current value in the GND layer is indicated as “−1” at positions of coordinates (x1, y5) and (x9, y5). The current value in the GND layer is indicated as “−4” at positions of coordinates (x2, y5) and (x8, y5). The current value in the GND layer is “−5” at positions of coordinates (x3, y5) to (x7, y5). The current value in the GND layer is indicated as “−2” at positions of coordinates (x2, y6) to (x8, y6). The current value in the GND layer is indicated as “0” at positions other than those of the coordinates mentioned above. As a result, in the GND layer, a strong current flows at the positions of the coordinates (x2, y5) to (x8, y5) compared to positions of other coordinates.

In FIG. 2A to FIG. 2C, the signs of current values in the signal layer and current values in the GND layer refer to directions in which the currents flow. As a result, in the example of FIG. 2A to FIG. 2C, a current flowing in the GND layer flows in a direction opposite to that of a current flowing in the signal layer.

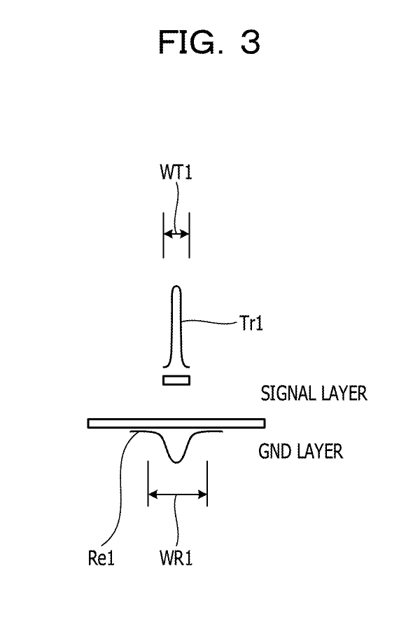

The combined range information 41 may be data indicating a range in which currents are combined. For example, the combined range information 41 stores values each indicating the length of a range for combining currents with the coordinates detected by the detection unit 52 as the center. FIG. 3 illustrates an example of a combined range. In FIG. 3, an example where a signal current Tr1 flows in the signal layer, a return current Re1 flows in the GND layer, and the signal current Tr1 is opposite in flow direction to the return current Re1. A width WR1 of the return current Re1 is wide compared to a width WT1 of the signal current Tr1 as illustrated in FIG. 3. For this reason, a combined current may be computed such that a spread of a return current is taken into account. For example, in order to accumulate a return current having a spread, a combined range indicating the range in which currents are combined is set.

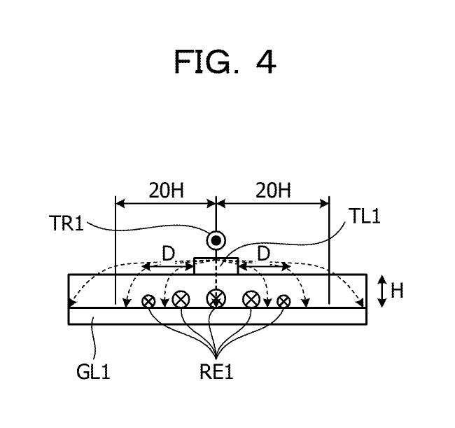

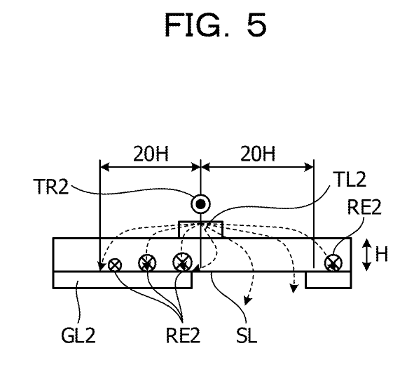

FIG. 4 and FIG. 5 illustrate examples of a combined range. In FIG. 4, a GND layer GL1 is present just under a signal current TR1 flowing in a signal layer TL1. In FIG. 4, the layer thickness, which is the distance between the signal layer TL1 and the GND layer GL1, is “H”. In FIG. 4, a return current RE1 flowing in the GND layer GL1 has a spread with a width D from the center of the signal layer TL1 in which the signal current TR1 flows. In FIG. 4, the width D is less than 20 H, which is 20 times the layer thickness H. In such a case where the width D is less than 20 H, the radiation noise may not increase.

In FIG. 5, there is a portion where a slit SL is present just under a signal current TR2 flowing in a signal layer TL2 and where a GND layer GL2 is absent. In FIG. 5, the layer thickness, which is the distance between the signal layer TL2 and the GND layer GL2, is “H”. In FIG. 5, a return current RE2 flowing in the GND layer GL2 has a spread with a width of 20 H or more from the center of the signal layer TL2 in which the signal current TR2 flows. In such a case where the width of a return current is 20 H or more, the radiation noise may increase. Therefore, as a combined range, a value of 20 times the layer thickness may be set.

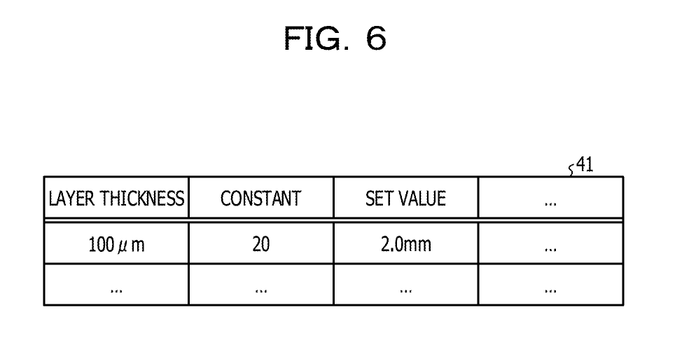

FIG. 6 depicts an example of data of combined range information. The combined range information 41 may be a table in which items of a layer thickness, a constant, a set value, and so on are associated with one another. The item of a layer thickness is an area storing the thickness of a layer between the signal layer and the GND layer of the circuit board. For example, the thickness of a layer between the signal layer and the GND layer detected from a layer definition file of a computer-aided design (CAD)-produced drawing or the like is stored in the layer thickness item. The item of a constant is an area storing a numeric value set in advance by the user. For example, in the item of a constant, an optimum numeric value representing the relationship between the layer thickness and the radiation noise obtained by an experiment or the like is stored. For example, in the item of a constant, since the width of a return current with which the radiation noise increases has a value of 20 times the layer thickness, “20” is stored. The item of a set value is an area storing the numeric value of a combined range representing a range where currents are combined. For example, in the item of a set value, a numeric value obtained by multiplying the layer thickness by a constant is stored.

In FIG. 6, the set value of the combined range may be “2 mm”, which is a value obtained by multiplying a thickness “100 μm” by a constant “20”.

The threshold information 42 is data serving as a criterion for determination of an area that is a possible noise source in the circuit board. For example, a threshold of the current value of a current flowing in the signal layer is stored in the threshold information 42. For example, the threshold of the current value is set to an arbitrary value in accordance with a processing load on the computing device 10 caused by arithmetic processing of a combined current.

The input unit 33 illustrated in FIG. 1 is an input device for inputting various kinds of information. As the input unit 33, an input device, such as a mouse or a keyboard, that receives input of operations may be employed. For example, running operations for running an electromagnetic field simulation are input to the input unit 33 by the user. Information related to the combined range information 41 and the threshold information 42 is input to the input unit 33 by the user. For example, numeric values used for computation of a combined range and a numeric value serving as a threshold are input to the input unit 33.

The display unit 34 may be a device, such as a liquid crystal display, that displays various kinds of information. For example, the display unit 34 displays various kinds of information in accordance with instructions of the output control unit 56. For example, the display unit 34 displays noise source distribution generated by the output control unit 56. For example, the display unit 34 displays distribution representing current values of a second combined current, as the noise source distribution.

The control unit 32 may be a device that controls the computing device 10. As the control unit 32, an electronic circuit such as a central processing unit (CPU) or a micro processing unit (MPU), or an integrated circuit such as an application specific integrated circuit (ASIC) or a field programmable gate array (FPGA) may be employed. The control unit 32 includes an internal memory for storing programs defining various processing procedures and control data and executes various processes based on the programs. The control unit 32 may function as various processing units when various programs are running. For example, the control unit 32 includes a receiving unit 50, a simulation unit 51, a detection unit 52, an extraction unit 53, a first computing unit 54, a second computing unit 55, and an output control unit 56.

The receiving unit 50 may be a processing unit that receives various kinds of information. For example, the receiving unit 50 receives a running operation for run of an electromagnetic field simulation by the simulation unit 51. The receiving unit 50 receives information related to the combined range information 41 and the threshold information 42 input through the input unit 33. For example, the receiving unit 50 receives a numeric value used for computation of a combined range and stores the received numeric value in the item of a constant of the combined range information 41. For example, the input unit 33 may receive a numeric value serving as a threshold and store the received numeric value in the threshold information 42.

The simulation unit 51 runs an electromagnetic field simulation. For example, when a running operation is received by the receiving unit 50, the simulation unit 51 computes the distribution of a current flowing in the signal layer and a current flowing in the GND layer of the circuit board. For example, the simulation unit 51 computes a current value in the signal layer and a current value in the GND layer for each coordinates on the circuit board. For example, the simulation unit 51 computes a current value in the signal layer and a current value in the GND layer by a finite-difference time-domain (FDTD) method. The simulation unit 51 stores the computed current values in the signal layer and in the GND layer in association with the coordinates in the current information 40.

The detection unit 52 detects information on a possible noise source. For example, the coordinates of an area where a current greater than or equal to a threshold flows are detected in the circuit board. For example, the detection unit 52 obtains a threshold for current values stored in the threshold information 42. The detection unit 52 obtains a current value in the signal layer for each coordinates stored in the current information 40. The detection unit 52 detects the coordinates in the signal layer at which a current greater than or equal to the obtained threshold flows.

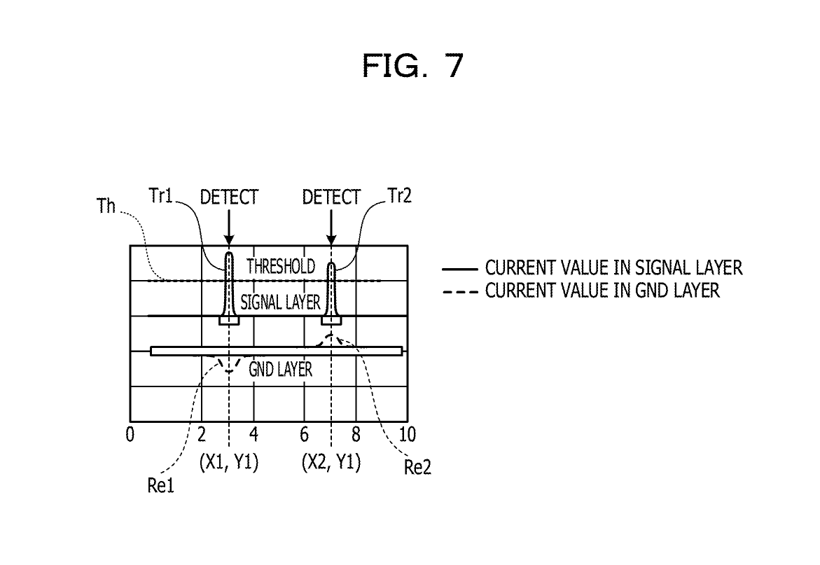

FIG. 7 illustrates an example of a detection process. In FIG. 7, an example where the signal current Tr1 flows in the signal layer at a position of coordinates (X1, Y1) is illustrated. An example where the signal current Tr2 flows in the signal layer at a position of coordinates (X2, Y1) is illustrated. An example where the return current Re1 flows in the GND layer at the position of the coordinates (X1, Y1) is illustrated. An example where the return current Re2 flows in the GND layer at the position of the coordinates (X2, Y1) is illustrated. The return current Re1 flows in a direction opposite to that of the signal current Tr1. As a result, at the position of the coordinates (X1, Y1), the signal current Tr1 and the return current Re1 are normal mode currents that cancel each other out. The return current Re2 flows in the same direction as that of the signal current Tr2. As a result, at the position of the coordinates (X2, Y1), the signal current Tr2 and the return current Re2 are common mode currents that do not cancel each other out and enhance each other.

The signal current Tr1 and the signal current Tr2 have current values greater than or equal to a threshold Th as illustrated in FIG. 7. For this reason, in FIG. 7, the detection unit 52 detects the coordinates (X1, Y1) and the coordinates (X2, Y1) as the coordinates of areas where currents greater than or equal to the threshold Th flow.

The extraction unit 53 illustrated in FIG. 1 extracts current values in the signal layer and current values in the GND layer based on the coordinates detected by the detection unit 52. For example, the extraction unit 53 extracts current values within a given range for each of the signal layer and the GND layer from the coordinates detected by the detection unit 52. For example, the extraction unit 53 extracts current values within a combined range with the coordinates detected by the detection unit 52 as the center.

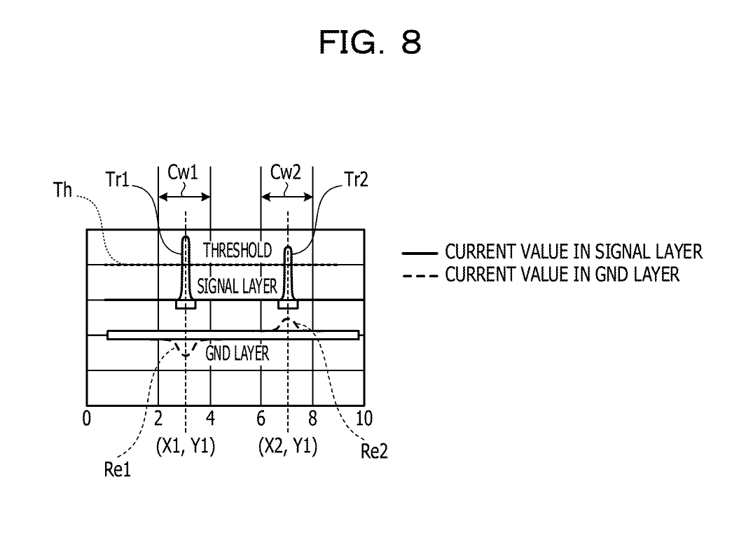

FIG. 8 illustrates an example of an extraction process. In FIG. 8, the extraction unit 53 extracts current values of the signal current Tr1 within a combined range Cwt with the coordinates (X1, Y1) as the center. The extraction unit 53 extracts current values of the signal current Tr2 within a combined range Cw2 with the coordinates (X2, Y1) as the center.

The first computing unit 54 computes, for each layer, a first combined current resulting from combination in a current within a combined range. For example, the first computing unit 54 computes a first combined current as a sum of extracted current values for each of the signal layer and the GND layer. For example, the first computing unit 54 computes the current value of a first combined current in the signal layer by integrating extracted current values within the combined range in the signal layer. The first computing unit 54 computes the current value of a first combined current in the GND layer by integrating extracted current values within the combined range in the GND layer.

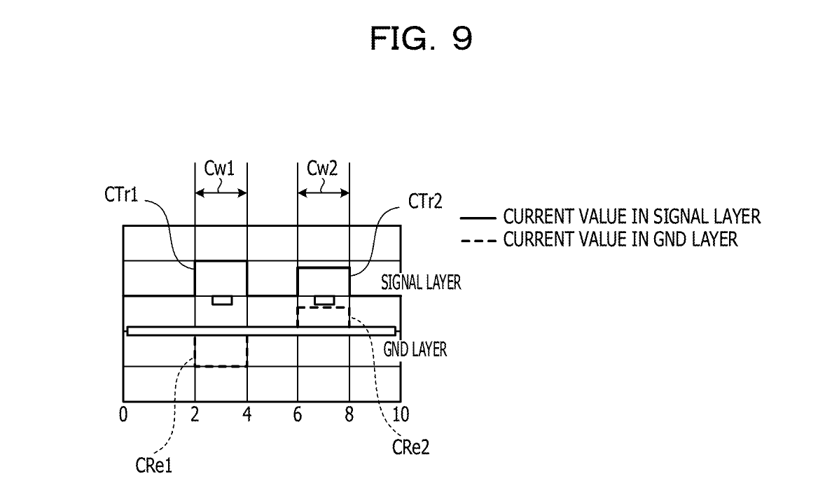

FIG. 9 illustrates an example of a first computing process. As illustrated in FIG. 9, the first computing unit 54 computes a first combined current CTr1 in the signal layer resulting from integration of the signal current Tr1 within the combined range Cwt in the signal layer illustrated in FIG. 8. The first computing unit 54 computes a first combined current CTr2 in the signal layer resulting from integration of the signal current Tr2 within the combined range Cw2 in the signal layer illustrated in FIG. 8. The first computing unit 54 computes a first combined current CRe1 in the GND layer resulting from integration of the return current Re1 within the combined range Cwt in the GND layer illustrated in FIG. 8. The first computing unit 54 computes a first combined current CRe2 in the GND layer resulting from integration of the return current Re2 within the combined range Cw2 in the GND layer illustrated in FIG. 8.

The second computing unit 55 computes a second combined current flowing in the section direction. For example, the second computing unit 55 computes the second combined current as a sum of the first combined current in the signal layer and the first combined current in the GND layer computed by the first computing unit 54 in the section direction. For example, the second computing unit 55 computes current values of the second combined current flowing in the section direction of the circuit board by adding current values in the section direction of the first combined current in the signal layer and current values in the section direction of the first combined current in the GND layer within the combined range. For example, the second computing unit 55 computes, for each position, a current value of the second combined current by adding the current value in the section direction of the first combined current in the signal layer and the current value in the section direction of the first combined current in the GND layer.

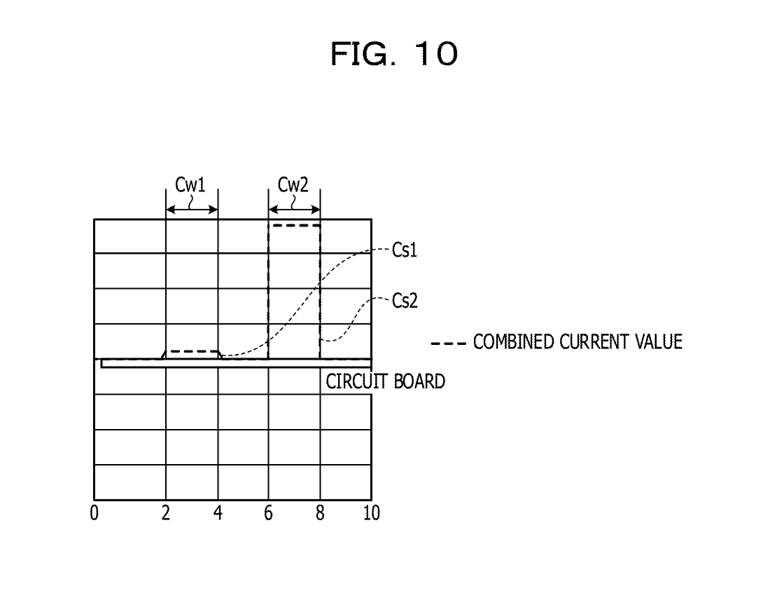

FIG. 10 illustrates an example of a second computing process. As illustrated in FIG. 10, the second computing unit 55 computes a second combined current Cs1 as a sum of the first combined current CTr1 in the signal layer and the first combined current CRe1 in the GND layer illustrated in FIG. 9 at each position within the combined range Cw1. The second computing unit 55 computes a second combined current Cs2 as a sum of the first combined current CTr2 in the signal layer and the first combined current CRe2 in the GND layer illustrated in FIG. 9 at each position within the combined range Cwt. In the example of FIG. 10, the second combined current Cs1 has a low current value because the first combined current CTr1 in the signal layer and the first combined current CRe1 in the GND layer, which are currents flow in opposite directions, cancel each other out. The second combined current Cs2 has a high current value because the first combined current CTr2 in the signal layer and the first combined current CRe2 in the GND layer, which are currents flowing in the same direction, do not cancel each other out but enhance each other. As a result, the second combined current Cs2 has a high radiation level compared with the second combined current Cs1. Accordingly, an area where the signal current Tr2 flows is highly likely to be a noise source compared with an area where the signal current Tr1 flows. Taking measures for reducing noise for the area where the signal current Tr2 flows may reduce noise effectively compared with the case in which measures are preferentially taken for an area where the signal current Tr1 having a higher current value than that of the signal current Tr2 flows.

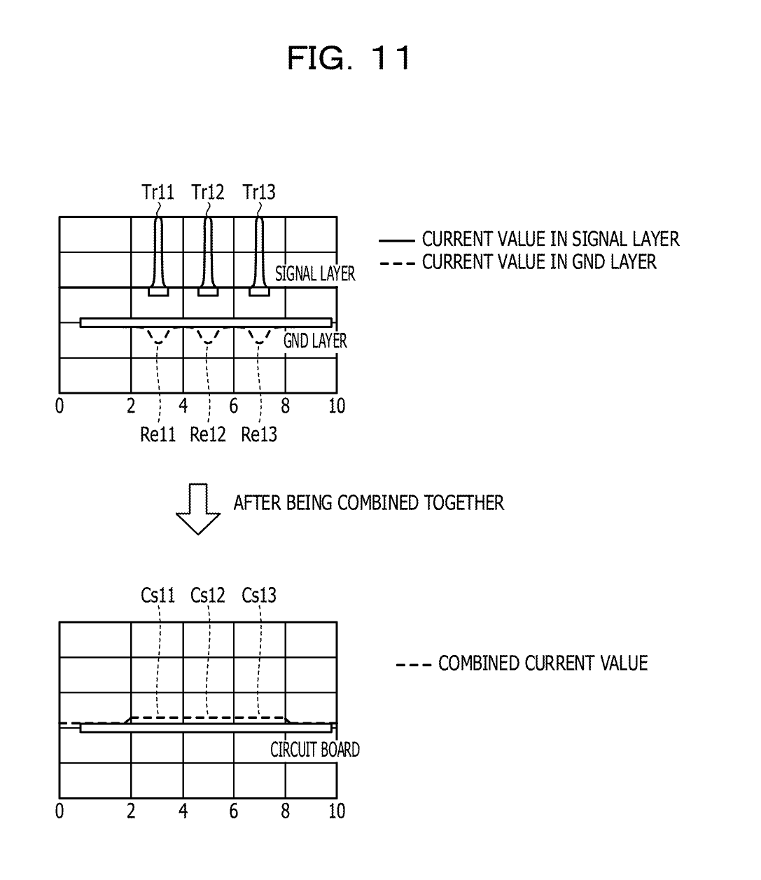

FIG. 11 illustrates an example of combined currents in a match pattern. In FIG. 11, signal currents Tr11 to Tr13 flow in the signal layer. In FIG. 11, return currents Re11 to Re13 flow in the GND layer below wiring in the signal layer. The return currents Re11 to Re13 flow in a direction opposite to that of the signal currents Tr11 to Tr13. In this case, the signal currents Tr11 to Tr13 and the return currents Re11 to Re13 cancel each other out within the combined range. As a result, second combined currents Cs11 to Cs13 flowing in the section direction of the circuit board have relatively low current values as illustrated in FIG. 11. Therefore, an area in the match pattern, which is relatively less affected by radiation, may not be a noise source.

FIG. 12 illustrates an example of a combined current at a circuit board end. In FIG. 12, signal currents Tr21 to Tr23 flow in the signal layer. In FIG. 12, return currents Re21 to Re23 flow in the GND layer below wiring in the signal layer. The signal current Tr21 flows in the signal layer at an end of the circuit board. As a result, the return current Re21 does not flow in a portion where the circuit board is absent, and a current value within the combined range is small compared with the return currents Re22 to Re23. In this case, the return current Re21 within the combined range that cancels the signal current Tr21 is small in amount compared with the return currents Re22 to Re23. As a result, a second combined current Cs21 flowing in the section direction of the circuit board has a high current value compared with second combined currents Cs22 to Cs23 as illustrated in FIG. 12. Therefore, the end of the circuit board, which is relatively more affected by radiation, may be a noise source.

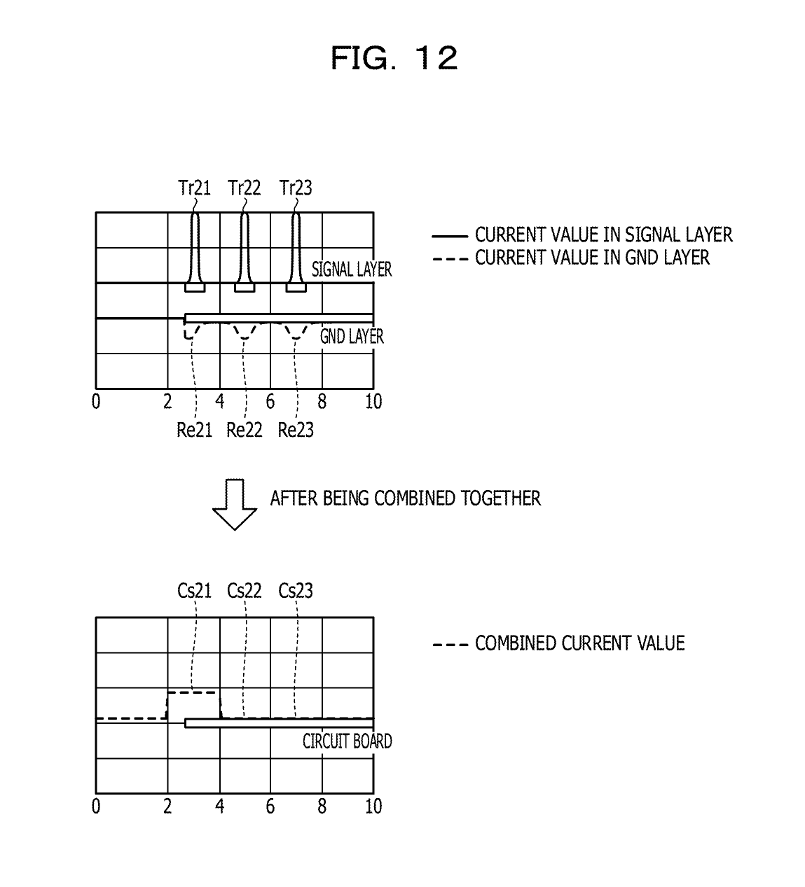

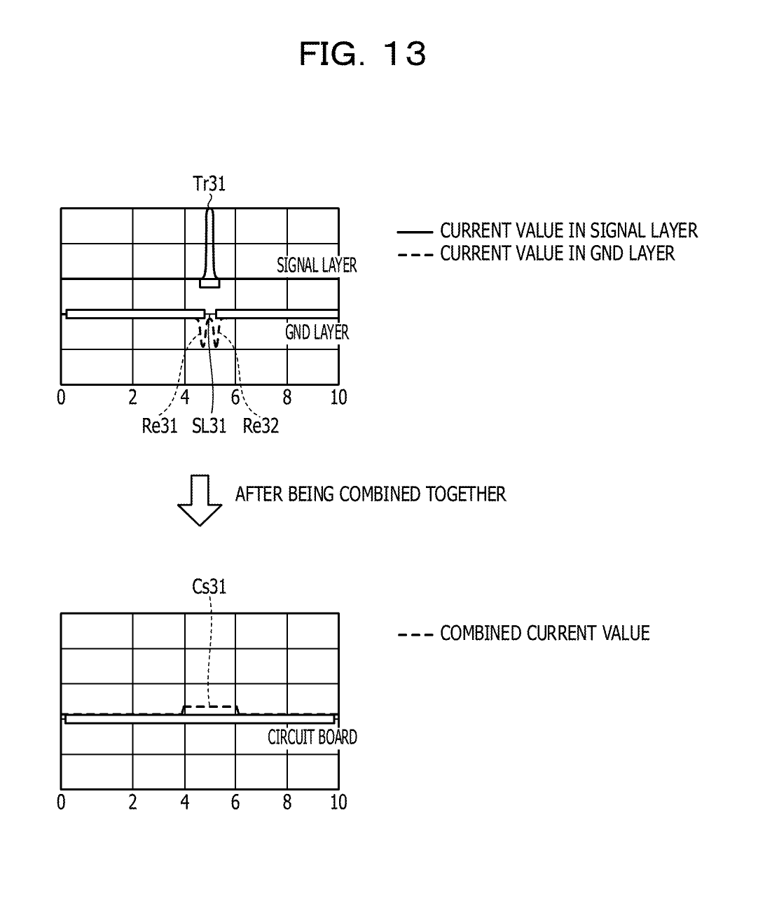

FIG. 13 illustrates an example of a combined current when there is a relatively short slit. In FIG. 13, a signal current Tr31 flows in the signal layer. In FIG. 13, return currents Re31 to Re32 flow in the GND layer below wiring in the signal layer. Under the signal layer where the signal current Tr31 flows, the GND layer having a relatively short slit SL31 is located. As a result, a return current does not flow in an area with the slit SL31 in the GND layer. However, in the vicinity of the slit SL31, the currents Re31 to Re32 in a direction opposite to that of the signal current Tr31 flow. In this case, the signal current Tr31 and the return currents Re31 to Re32 cancel each other out within the combined range. As a result, a second combined current Cs31 flowing in the section direction of the circuit board has a relatively low current value as illustrated in FIG. 13. Accordingly, an area with a relatively short slit, which is relatively less affected by radiation, may not be a noise source.

FIG. 14 illustrates an example of combined currents when there is a relatively long slit. In FIG. 14, a signal current Tr41 flows in the signal layer. In FIG. 14, return currents Re41 to Re42 flow in the GND layer below wiring in the signal layer. Under the signal layer where the signal current Tr41 flows, the GND layer having a relatively long slit SL41 is located. As a result, a return current does not flow in an area with the slit SL41 in the GND layer. Currents Re41 to Re42 in a direction opposite to that of the signal current Tr41 flow at positions apart from the center of the slit SL41. In this case, the signal current Tr41 and the return currents Re41 to Re42 do not cancel each other out within the combined range. As a result, second combined currents Cs41 to Cs43 flowing in the section direction of the circuit board have high current values as illustrated in FIG. 14. Accordingly, an area with a relatively long slit, which is relatively more affected by radiation, may be a noise source.

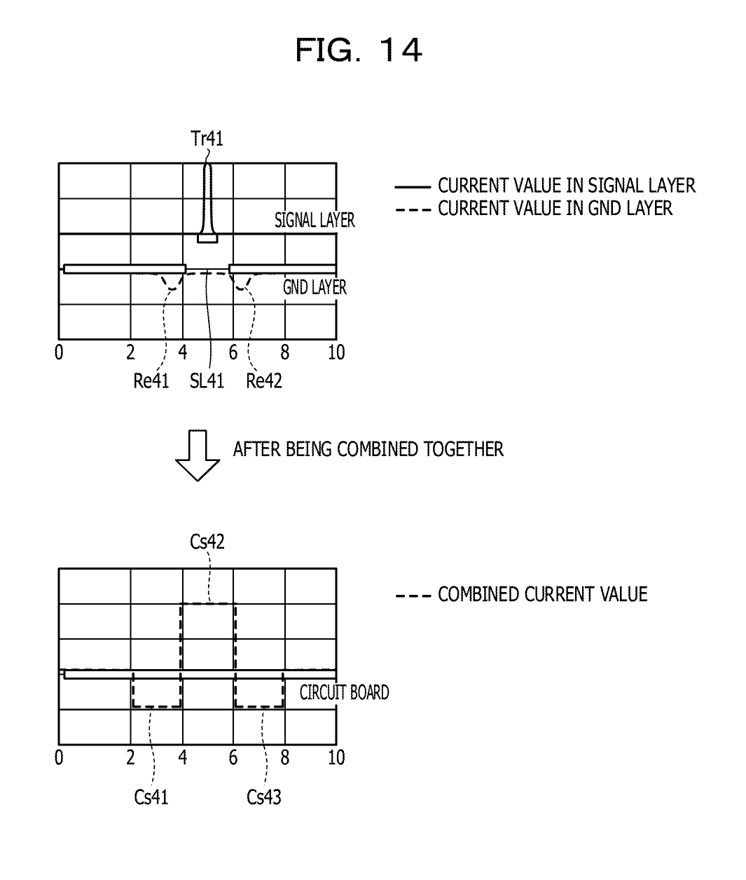

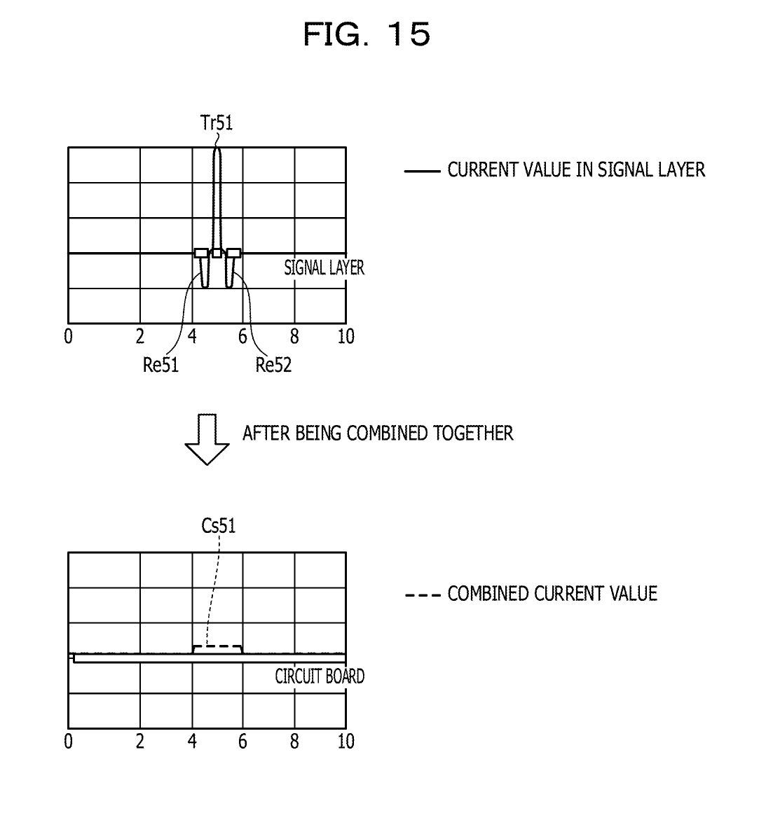

FIG. 15 illustrates an example of a combined current in a guard pattern case. The guard pattern is a pattern in which a signal current and return currents flow in the same layer. In FIG. 15, a signal current Tr51 flows in the signal layer. Return currents Re51 to Re52 flow in the signal layer. For example, in FIG. 15, the return currents Re51 to Re52 flow in the same layer as that of the signal current Tr51. The return currents Re51 to Re52 flow in a direction opposite to that of the signal current Tr51. In this case, the signal current Tr51 and the return currents Re51 to Re52 cancel each other out within the combined range. As a result, a second combined current Cs51 flowing in the section direction of the circuit board has a relatively low current value as illustrated in FIG. 15. Accordingly, the guard pattern, which is relatively less affected by radiation, may not be a noise source.

The output control unit 56 illustrated in FIG. 1 outputs information on a noise source. For example, the output control unit 56 outputs noise source distribution indicating intensities of radiation noise radiated from the circuit board based on a second combined current computed by the second computing unit 55. For example, the output control unit 56 outputs distribution of a current value as a sum of second combined currents in each given section on the circuit board.

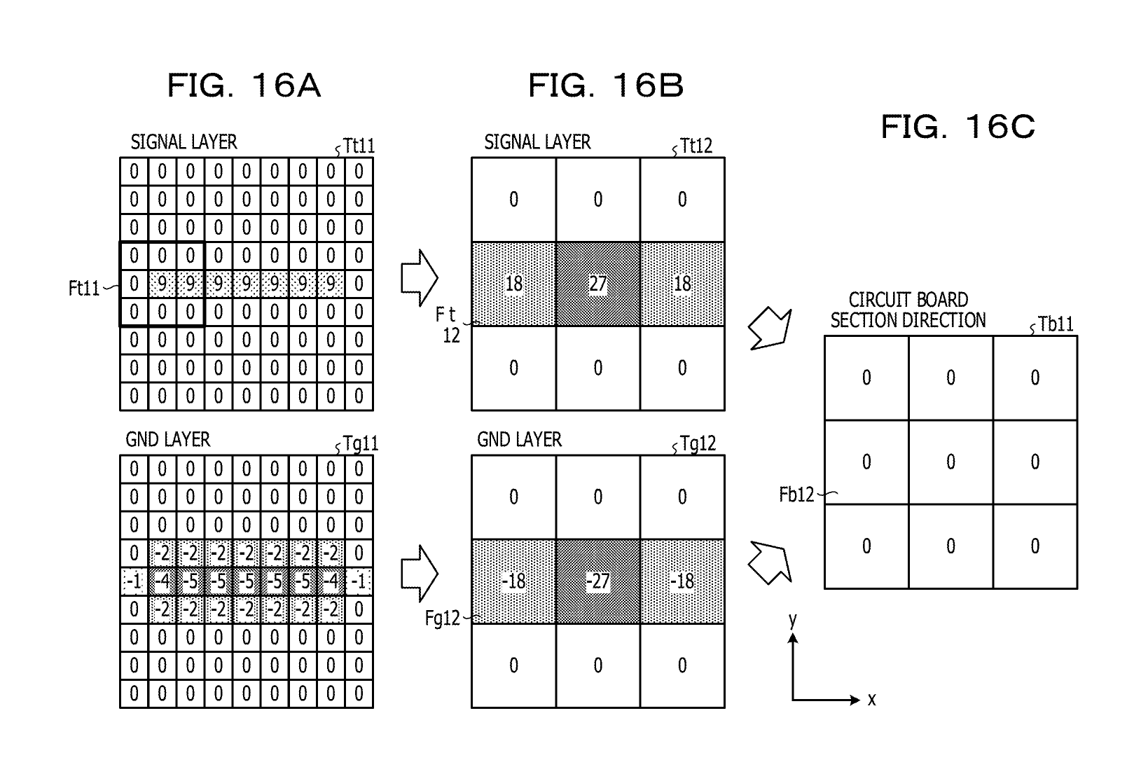

FIG. 16A to FIG. 16C illustrate an example of distribution of current values in a match pattern case. In FIG. 16A, as distribution Tt11, a table associating “Coordinates” with “Current value in signal layer” depicted in FIG. 2A to FIG. 2C is illustrated. For example, the distribution Tt11 indicates that the current value in the signal layer flowing at a position of coordinates (x1, y5) on the circuit board is “0”. For example, the distribution Tt11 indicates that the current value in the signal layer flowing at a position of coordinates (x2, y5) on the circuit board is “9”.

In FIG. 16A, as distribution Tg11, a table associating “Coordinates” with “Current value in GND layer” depicted in FIG. 2A to FIG. 2C is illustrated. For example, the distribution Tg11 indicates that the current value in the GND layer flowing at the position of coordinates (x1, y5) on the circuit board is “−1”. For example, the distribution Tg11 indicates that the current value in the GND layer flowing at the position of coordinates (x2, y5) on the circuit board is “−4”. In FIG. 16A to FIG. 16C, the sign refers to the direction in which a current flows. In FIG. 16A to FIG. 16C, the current flowing in the GND layer flows in a direction opposite to that of the current flowing in the signal layer.

In FIG. 16B, distribution Tt12 indicates the current value of a first combined current in the signal layer as a sum of current values in the signal layer in each given section on the circuit board. For example, the distribution Tt12 indicates the current value of a first combined current in the signal layer as a sum of current values in the signal layer of each matrix of 3×3 cells in the distribution Tt11 on the assumption that each coordinates indicated in the distribution Tt11 are one cell. For example, a frame Ft12 in the distribution Tt12 indicates a current value “18” of a first combined current in the signal layer as a sum of current values in the signal layer of coordinates (x1, y4) to coordinates (x3, y6) included in a frame Ft11 in the distribution Tt11. Similarly, distribution Tg12 indicates the current value of a first combined current in the GND layer as a sum of current values in the GND layer of each matrix of 3×3 cells in the distribution Tg11 on the assumption that each coordinates indicated in the distribution Tg11 are one cell. For example, a frame Fg12 in the distribution Tg12 indicates a current value “−18” of a first combined current in the GND layer as a sum of current values in the GND layer of coordinates (x1, y4) to coordinates (x3, y6) of the distribution Tg11.

In FIG. 16C, distribution Tb11 indicates the current values of second combined currents as sums of current values of first combined currents in the signal layer and current values of first combined currents in the GND layer in the section direction of the circuit board. For example, a frame Fb12 in the distribution Tb11 indicates a current value “0” as a sum of a current value “18” indicated in the frame Ft12 in the distribution Tt12 and a current value “−18” indicated in the frame Fg12 in the distribution Tg12, which is a position corresponding to the frame Ft12. As illustrated in FIG. 16A to FIG. 16C, in the distribution Tb11, the first combined current in the signal layer and the first combined current in the GND layer cancel each other out in each of all the frames, and thus the second combined currents in all the frames are indicated to be “0”. The output control unit 56 displays, for example, the distribution Tb11 on the display unit 34. Since, in the match pattern illustrated in FIG. 16A to FIG. 16C, the second combined currents in all the frames are “0”, the user may recognize that this match pattern, which is relatively less affected by radiation, is highly likely to be not a noise source.

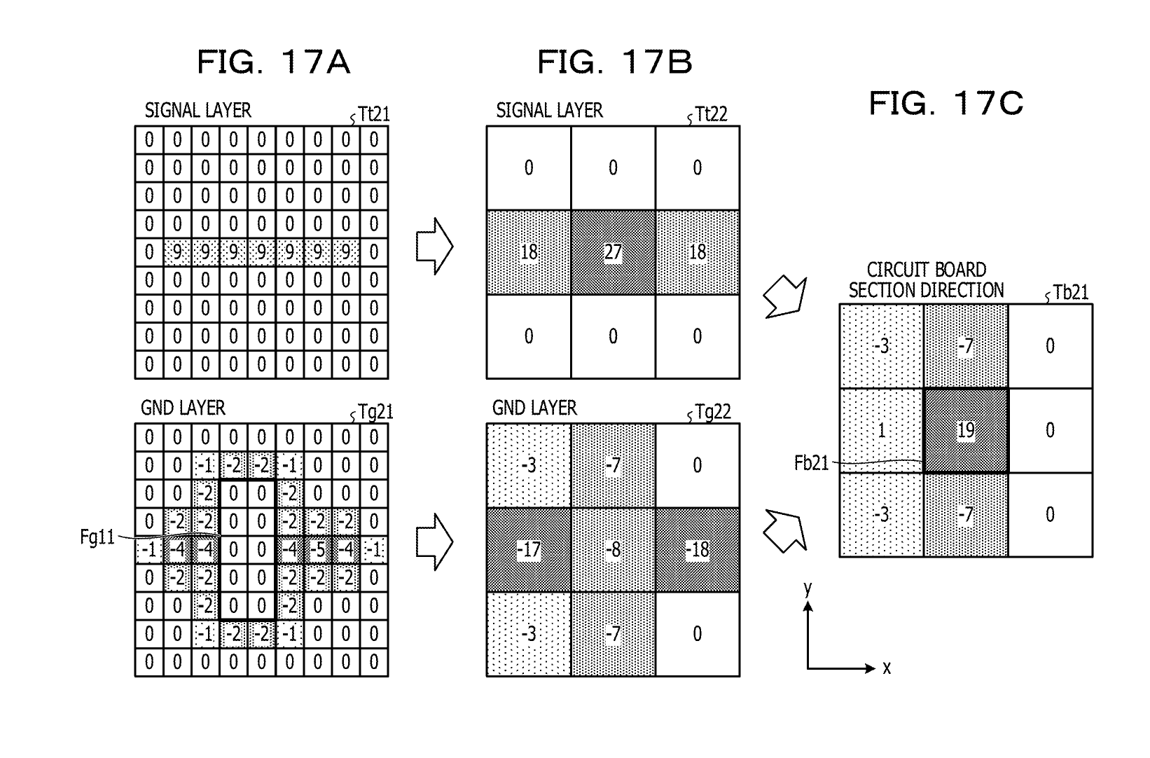

FIG. 17A to FIG. 17C illustrate an example of distribution of current values when there is a slit. In the example of FIG. 17A, distribution Tt21 indicates a table associating “Coordinates” on the circuit board with “Current value in signal layer” when there is a slit in the circuit board. In FIG. 17A, distribution Tg21 indicates a table associating “Coordinates” on the circuit board with “Current value in GND layer” when there is a slit in the circuit board. For example, there is a slit in the GND layer at positions of coordinates (x4, y3) to coordinates (x5, y7). As a result, the current values in the GND layer of coordinates (x4, y3) to coordinates (x5, y7) included in a frame Fg11 of the distribution Tg21 are “0”.

In FIG. 17B, distribution Tt22 indicates the current value of a first combined current in the signal layer as a sum of current values in the signal layer of each matrix of 3×3 cells in the distribution Tt21 on the assumption that each coordinates indicated in the distribution Tt21 are one cell. Distribution Tg22 indicates the current value of a first combined current in the GND layer as a sum of current values in the GND layer of each matrix of 3×3 cells in the distribution Tg21 on the assumption that coordinates indicated in the distribution Tg21 are one cell.

In FIG. 17C, distribution Tb21 indicates the current values of second combined currents as sums of the current values of first combined currents in the signal layer indicated in the distribution Tt22 and the current values of first combined currents in the GND layer indicated in the distribution Tg22 in the section direction of the circuit board. As illustrated in FIG. 17A to FIG. 17C, in the distribution Tb21, the current value indicated in a frame Fb21 is highest. This indicates that the positions corresponding to the frame Fb21 are relatively more affected by radiation. Accordingly, the distribution Tb21, in which the positions corresponding to the frame Fb21 are highly likely to be a noise source, may be given high priority for anti-noise measures.

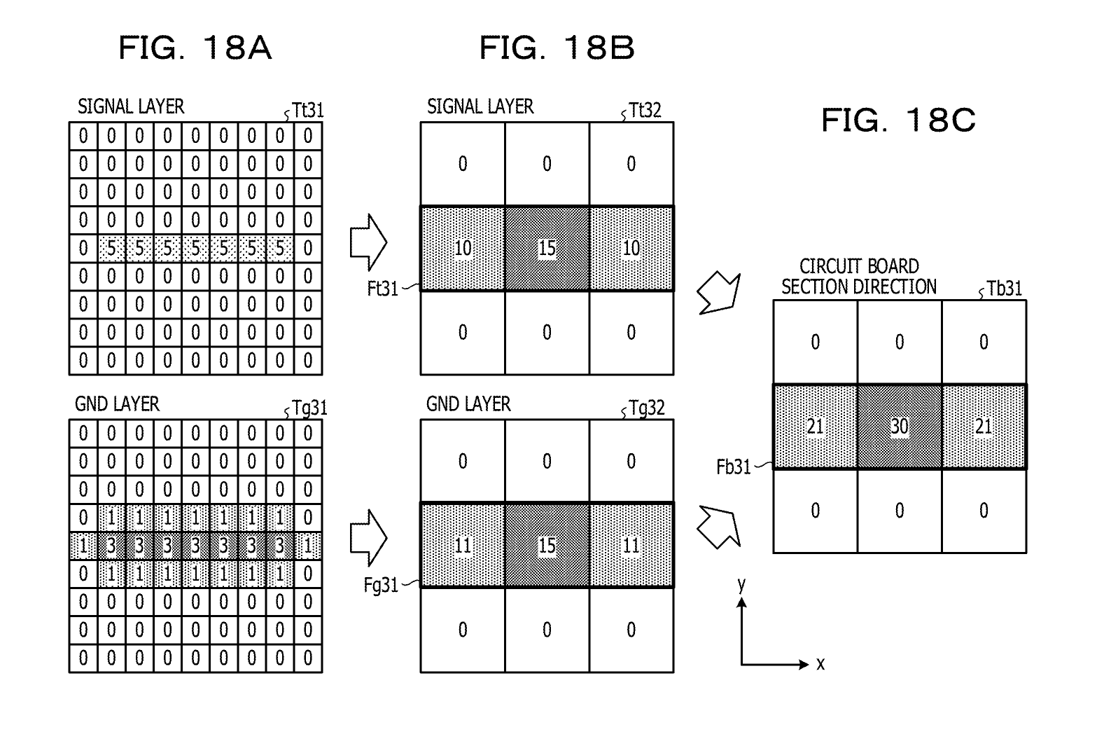

FIG. 18A to FIG. 18C illustrate an example of distribution of current values when a common mode current flows. In FIG. 18A, distribution Tt31 indicates a table associating “Coordinates” on the circuit board with “Current value in signal layer” when the common mode current flows. In FIG. 18B, distribution Tg31 indicates a table associating “Coordinates” on the circuit board with “Current value in GND layer” when the common mode current flows.

In FIG. 18B, distribution Tt32 indicates the current value of a first combined current in the signal layer as a sum of current values in the signal layer of each matrix of 3×3 cells in the distribution Tt31 on the assumption that each coordinates indicated in the distribution Tt31 are one cell. Distribution Tg32 indicates the current value of a first combined current in the GND layer as a sum of current values in the GND layer of each matrix of 3×3 cells in the distribution Tg31 on the assumption that each coordinates indicated in the distribution Tg31 are one cell.

In FIG. 18C, distribution Tb31 indicates the current values of second combined currents as sums of the current values of first combined currents in the signal layer indicated in the distribution Tt32 and the current values of second combined currents in the GND layer indicated in the distribution Tg32 in the section direction of the circuit board. As illustrated in FIG. 18A to FIG. 18C, in the distribution Tb31, since the first combined currents in the signal layer included in a frame Ft31 of the distribution Tt32 and the first combined currents in the GND layer included in a frame Fg31 of the distribution Tg32 flow in the same direction and enhance each other, the current values indicated in a frame Fb31 are relatively high. As a result, the distribution Tb31 indicates that the positions corresponding to the frame Fb31 are relatively more affected by radiation. Accordingly, the distribution Tb31, in which the positions corresponding to the frame Fb31 are highly likely to be a noise source, may be given high priority for anti-noise measures.

The output control unit 56 displays, for example, the distribution Tb11 to Tb31 indicating such intensities of radiation noise on the display unit 34. Therefore, referring to the distribution Tb11 to Tb31, the user may recognize positions more affected by radiation in the circuit board and may recognize an area that is highly likely to be a noise source. The user takes anti-noise measures preferentially for an area that is highly likely to be a noise source, which may increase the efficiency of the measures.

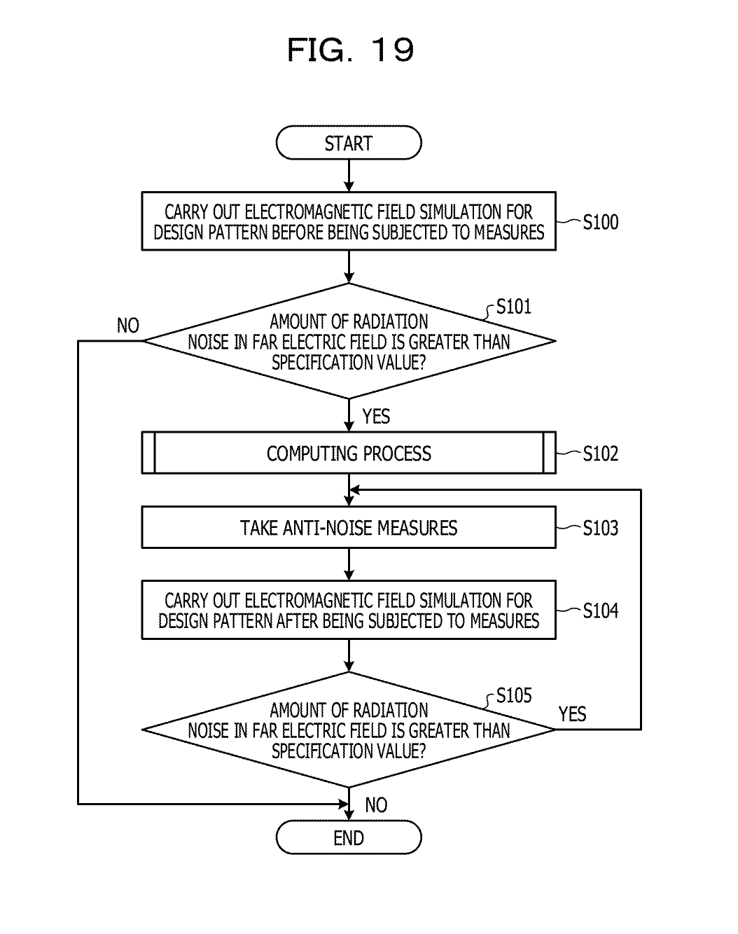

FIG. 19 illustrates an example of an anti-noise measures process. The anti-noise measures process illustrated in FIG. 19 may be executed by using the computing device 10 illustrated in FIG. 1. The anti-noise measures process illustrated in FIG. 19 may be executed at a given time, for example at a time at which execution operations are received by the receiving unit 50 of the computing device 10.

As illustrated in FIG. 19, the computing device 10 may carry out an electromagnetic field simulation for the current design pattern of the circuit board. For example, the computing device 10 carries out the electromagnetic field simulation for a design pattern before being subjected to anti-noise measures (S100). For such a design pattern before being subjected to the anti-noise measures, the computing device 10 obtains the value of a current flowing in the signal layer and the value of a current flowing in the GND layer in a near electromagnetic field and the amount of radiation noise in a far electric field. The computing device 10 then stores the computed current value flowing in the signal layer and current value flowing in the GND layer in association with coordinates in the current information 40.

The computing device 10 determines whether or not the amount of radiation noise in the far electric field is greater than a specification value (S101). If the amount of radiation noise in the far electric field is less than or equal to the specification value (negative in S101), then the computing device 10 completes the process. If the amount of radiation noise in the far electric field is greater than the specification value (affirmative in S101), the computing device 10 executes a computing process (S102). Thereby, the computing device 10 obtains noise source distribution.

The computing device 10 takes anti-noise measures based on the obtained noise source distribution (S103). For example, the computing device 10 takes anti-noise measures for areas in order from the highest priority, based on the current values of second combined currents. For example, the computing device 10 takes anti-noise measures in order from an area with the highest current value of a second combined current. For example, the computing device 10 changes the design pattern by changing the shape of the GND layer, as anti-noise measures. For example, the computing device 10 changes the design pattern by arranging a capacitor in a slit portion of the GND pattern in order to cause a return current to flow close to the signal current, as anti-noise measures. For example, the computing device 10 changes the design pattern by arranging a resistor in order to convert current to heat, as anti-noise measures.

The computing device 10 carries out an electromagnetic field simulation for a design pattern after being subjected to the anti-noise measures (S104). For such a design pattern after being subjected to the anti-noise measures, the computing device 10 obtains a current value flowing in the signal layer and a current value flowing in the GND layer in the near electromagnetic field and the amount of radiation noise in the far electric field. The computing device 10 stores the computed current value flowing in the signal layer and current value flowing in the GND layer in association with coordinates in the current information 40.

The computing device 10 determines whether or not the amount of radiation noise in the far electric field is greater than a specification value (S105). If the amount of radiation noise in the far electric field is less than or equal to the specification value (negative in S105), then the computing device 10 completes the process. If the amount of radiation noise in the far electric field is greater than the specification value (affirmative in S105), then the computing device 10 repeatedly performs the process in S103 to S105.

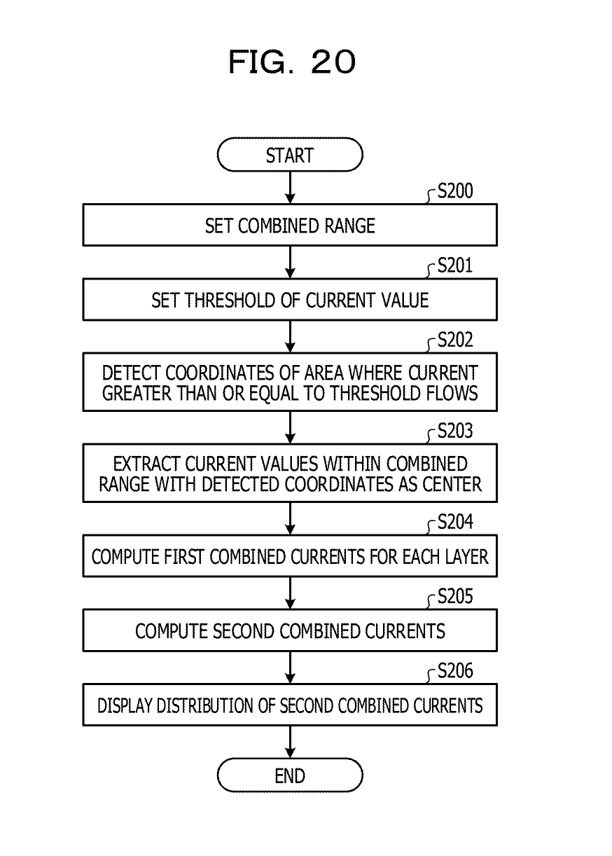

FIG. 20 illustrates an example of a computing process. The computing process illustrated in FIG. 20 may be executed by the computing device 10 illustrated in FIG. 1. As illustrated in FIG. 20, the computing device 10 sets a combined range in which currents are combined (S200). For example, the computing device 10 stores “Layer thickness”, which is detected from a layer definition file of a CAD-produced drawing or the like, and “Constant”, which is received by the receiving unit 50, in the combined range information 41. The computing device 10 then sets, as a combined range, “Set value” obtained by multiplication of the “Layer thickness” and the “Constant” stored in the combined range information 41.

The computing device 10 sets a threshold of a current value in the signal layer serving as a criterion for determining an area that is a possible noise source in the circuit board (S201). For example, the computing device 10 stores a numeric value received as a threshold by the receiving unit 50 in the threshold information 42, thereby setting the threshold of a current value.

The computing device 10 detects, in the circuit board, coordinates of an area where a current greater than or equal to the threshold flows (S202). For example, the computing device 10 obtains the threshold of a current value stored in the threshold information 42. The computing device 10 obtains the current value in the signal layer for each coordinates stored in the current information 40. The computing device 10 detects the coordinates in the signal layer at which a current greater than or equal to the obtained threshold flows.

The computing device 10 extracts current values in a given range for each of the signal layer and the GND layer from the detected coordinates. For example, the computing device 10 obtains “Set value” as a combined range from the combined range information 41. Using the “Set value” as the combined range, the computing device 10 extracts current values within the combined range with the detected coordinates as the center (S203).

The computing device 10 computes the first combined currents for each of the layers (S204). For example, the computing device 10 computes first combined currents as sums of the extracted current values for each of the signal layer and the GND layer. For example, the computing device 10 computes first combined currents in the signal layer by integrating the extracted current values within the combined range in the signal layer. The computing device 10 computes first combined currents in the GND layer by integrating the extracted current values within the combined range in the GND layer.

The computing device 10 computes second combined currents (S205). For example, the computing device 10 computes second combined currents as sums of the computed first combined currents in the signal layer and first combined currents in the GND layer in the section direction. For example, the computing device 10 adds the current values in the section direction of the first combined currents in the signal layer and the current values in the section direction of the first combined currents in the GND layer together within the combined range, thereby computing the current values of second combined currents flowing in the section direction of the circuit board.

The computing device 10 displays noise source distribution based on the computed second combined currents (S206) and completes the process. For example, the computing device 10 displays noise source distribution indicating intensities of radiation noise radiated from the circuit board based on the computed second combined currents. For example, the computing device 10 displays, as noise source distribution, distribution of current values as sums of second combined currents in each given section on the circuit board.

The computing device 10 detects, in the circuit board, the coordinates of an area where a current greater than or equal to a threshold flows. The computing device 10 extracts, from the detected coordinates, current values within a given range for each of the signal layer and the GND layer. The computing device 10 computes first combined currents as sums of the extracted current values for each of the signal layer and the GND layer. The computing device 10 computes second combined currents as sums of the computed first combined currents in the signal layer and first combined currents in the GND layer in the section direction. Thus, the computing device 10 recognize the intensities of radiation noise based on the second combined currents and therefore may identify a noise source. For example, the computing device 10 computes second combined currents and thus accurately identifies, for areas, the order of priority in which anti-noise measure are to be taken. This may reduce the number of times the electromagnetic field simulation is repeated. The computing device 10 takes anti-noise measures efficiently and thus may reduce time and energy of the user.

The computing device 10 outputs noise source distribution indicating the intensities of radiation noise radiated from the circuit board based on the computed second currents. As a result, with the computing device 10, the user may recognize, in the circuit board, positions more affected by radiation. Therefore, an area that is highly likely to be a noise source may be easily recognized. With the computing device 10, the measures are taken preferentially for an area that is highly likely to be a noise source, and thus the efficiency of the measures may be increased.

The computing device 10 outputs, as noise source distribution, distribution of current values as a sum of second currents in each given section on the circuit board. Therefore, the computing device 10 enables the positions more affected by radiation to be recognized in the circuit board using numeric values, and thus an area that is highly likely to be a noise source may be recognized more clearly. With the computing device 10, the measures are taken more locally for an area that is highly likely to be a noise source, and thus the effect of the measures may increase.

The techniques described above may be carried out in various different forms.

For example, as noise source distribution, distribution of current values as a sum of second combined currents in each given section on the circuit board may be output. For example, the computing device 10 may output, as noise source distribution, distribution of current values represented by vectors.

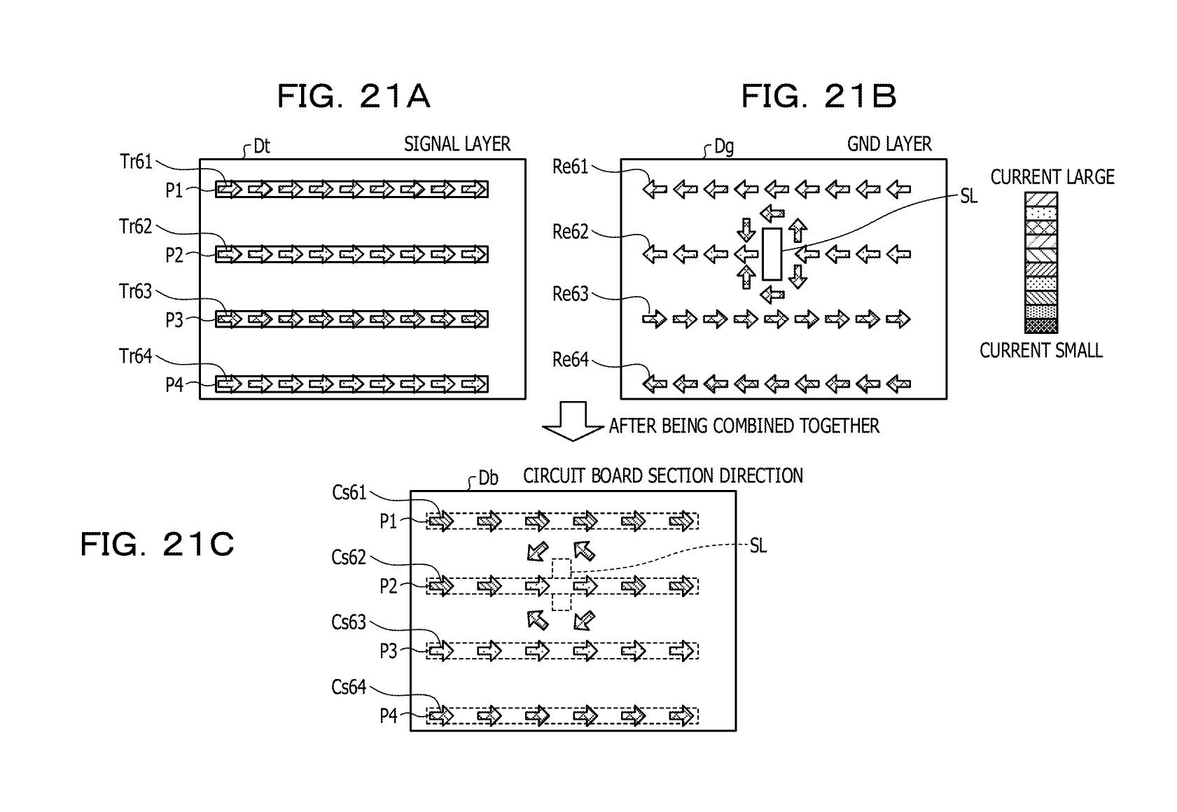

FIG. 21A to FIG. 21C illustrate an example of distribution of current values represented by vectors. In FIG. 21A, distribution Dt indicates the current values represented by vectors of signal currents Tr61 to Tr64 flowing in the signal layer. In FIG. 21B, distribution Dg indicates the current values represented by vectors of return currents Re61 to Re64 flowing in the GND layer. In FIG. 21A to FIG. 21C, the directions of arrows refer to directions in which currents flow. The signal current Tr61 and the return current Re61 flow, in the circuit board, at a position P1 of a match pattern. The signal current Tr62 and the return current Re62 flow, in the circuit board, at a position P2 where there is a slit SL. The signal current Tr63 and the return current Re63 flow, in the circuit board, at a position P3 where a common mode current flows. The signal current Tr64 and the return current Re64 flow, in the circuit board, at a position P4 at a board end.

In FIG. 21C, distribution Db indicates the current values represented by vectors of second combined currents Cs61 to Cs64 as sums of the signal currents Tr61 to Tr64 and the return currents Re61 to Re64 in the section direction of the circuit board. As illustrated in FIG. 21C, the current value of the second combined current Cs63 flowing, in the circuit board, at the position P3 where a common mode current flows is largest compared with the second combined current Cs61, the second combined current Cs62, and the second combined current Cs64. As a result, in FIG. 21A to FIG. 21C, the position P3 where the second combined current Cs63 flows is a noise source for which it is most preferable that the measures be taken. Preferentially taking anti-noise measures for the position P3 may efficiently reduce noise.

The signal currents Tr61 to Tr64 have current values in order from the largest value to the smallest, the signal current Tr62, the signal current Tr64, and the signal current Tr63. As a result, when anti-noise measure are taken in order from the largest current value among the signal currents Tr61 to Tr64 flowing in the signal layer, not the second combined currents Cs61 to Cs64, the measures are taken in the order of the position P1, the position P2, the position P4, and the position P3. In this case, there are three positions before the position 3 at which it is most preferable that anti-noise measures be taken.

When the measures are taken based on the current values of second combined currents, anti-noise measures are first taken for the position P3. As a result, when the measures are taken based on the current values of second combined currents, anti-noise measures may be taken more efficiently compared with the case where the measures are taken based on the current values of signal currents. For example, when the measures are taken based on the current values of second combined currents, the number of times where anti-noise measures are taken for the position P3 is three smaller than in the case where the measures are taken based on the current values of signal currents. This may reduce time and energy of the user.

All the components of each of devices illustrated in the drawings may not be physically configured as illustrated in the drawings. For example, all or part of the distribution and integration of each device may be made as functional or physical distribution and integration in any units in accordance with various loads and usage situations. For example, processing units of the computing device 10 including the receiving unit 50, the simulation unit 51, the detection unit 52, the extraction unit 53, the first computing unit 54, the second computing unit 55, and the output control unit 56 may be suitably integrated. The processing of all the processing units may be suitably separated into the processing of a plurality of processing units. All or any part of all the processing functions performed in all the processing units may be implemented by a CPU or a program analyzed and executed on the CPU and may also be implemented as hardware by wired logic.

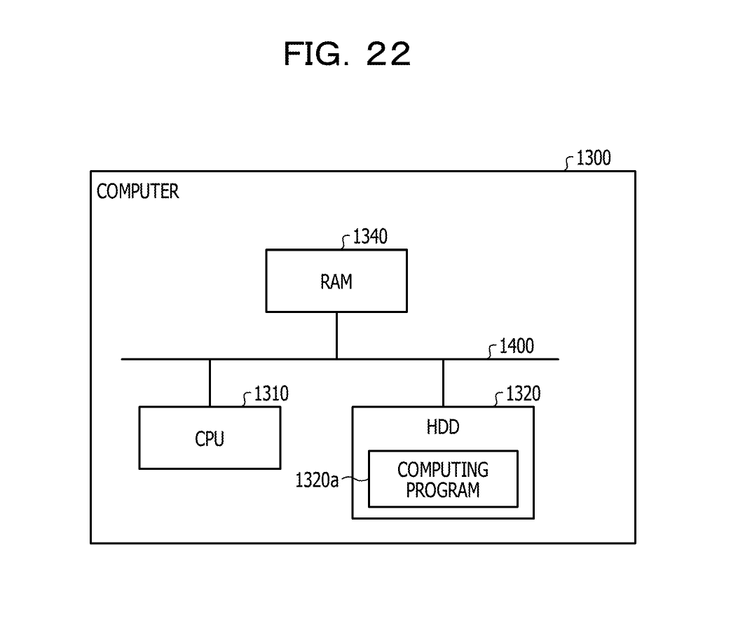

The various processes described above may be implemented when a program provided in advance is executed on a computer system such as a personal computer or a work station. FIG. 22 illustrates an example of a computer system. The computer system illustrated in FIG. 22 may execute a program having the functions described above, for example, a computing program.

As illustrated in FIG. 22, a computer 1300 includes a CPU 1310, a hard disk drive (HDD) 1320, and a random access memory (RAM) 1340. These units 1300 to 1340 are coupled via a bus 1400.

In the HDD 1320, a computing program 1320a that exert functions similar to those of the receiving unit 50, the simulation unit 51, the detection unit 52, the extraction unit 53, the first computing unit 54, the second computing unit 55, and the output control unit 56 of the computing device 10 described above is stored in advance. The computing program 1320a may be suitably separated.

The HDD 1320 stores various kinds of information. For example, the HDD 1320 stores various kinds of data used for the OS and computing processes.

The CPU 1310 reads the computing program 1320a from the HDD 1320 and executes it, thereby executing operations similar to those of the processing units described above. For example, the computing program 1320a may perform operations similar to those of the receiving unit 50, the simulation unit 51, the detection unit 52, the extraction unit 53, the first computing unit 54, the second computing unit 55, and the output control unit 56 of the computing device 10.

The computing program 1320a mentioned above does not have to be originally stored in the HDD 1320.

For example, from a “portable physical medium”, such as a flexible disk (FD), a compact disk read-only memory (CD-ROM), a digital versatile disk (DVD), a magneto-optical disk, or an integrated circuit (IC) card, that is inserted into the computer 1300, the computer 1300 may read a program and execute it.

“Another computer (or server)” or the like coupled to the computer 1300 via a public network, the Internet, a local area network (LAN), a wide area network (WAN), or the like may store a program, and the computer 1300 may read the program from it and execute the program.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A computing method comprising:
detecting, in a circuit board, a coordinate of an area where a current greater than or equal to a threshold flows;
extracting signal layer currents and GND layer currents within a given range based on the coordinate, the signal layer currents flowing in a signal layer and the GND layer currents flowing in a GND layer;
computing, by a computer, a first current as a sum of the signal layer currents and a second current as a sum of the GND layer currents; and
computing a third current as a sum of the first current and the second current in a section direction of the circuit board.

2. The computing method according to claim 1, wherein the signal layer currents and the GND layer currents at the coordinate flow in one direction or in a direction in which the signal layer currents and the GND layer currents cancel each other out.

3. The computing method according to claim 1,
wherein the first current is computed by integration of the signal layer currents within the given range, and
wherein the second current is computed by integration of the GND layer currents within the given range.

4. The computing method according to claim 1, wherein the given range is a range with the coordinate as a center and is obtained by multiplication of a thickness of a distance between the signal layer and the GND layer by a given number.

5. The computing method according to claim 1, further comprising:
outputting noise source distribution indicating intensities of radiation noise radiated from the circuit board based on the third current.

6. The computing method according to claim 5, wherein, as the noise source distribution, distribution of a current value as a sum of the third current in each given section on the circuit board is output.

7. A computing device comprising:
a processor configured to execute a program; and
a memory configured to store the program,
the processor, based on the program, configured to:
detect, in a circuit board, a coordinate of an area where a current greater than or equal to a threshold flows;
extract signal layer currents and GND layer currents within a given range based on the coordinate, the signal layer currents flowing in a signal layer and the GND layer currents flowing in a GND layer;
compute a first current as a sum of the signal layer currents and a second current as a sum of the GND layer currents; and
compute a third current as a sum of the first current and the second current in a section direction of the circuit board.

8. The computing device according to claim 7, wherein the signal layer currents and the GND layer currents at the coordinate flow in one direction or in a direction in which the signal layer currents and the GND layer currents cancel each other out.

9. The computing device according to claim 7,
wherein the processor configured to compute the first current by integration of the signal layer currents within the given range, and compute the second current by integration of the GND layer currents within the given range.

10. The computing device according to claim 7, wherein the given range is a range with the coordinate as a center and is obtained by multiplication of a thickness of a distance between the signal layer and the GND layer by a given number.

11. The computing device according to claim 7, wherein the processor is configured to output noise source distribution indicating intensities of radiation noise radiated from the circuit board based on the third current.

12. The computing device according to claim 11, wherein the processor is configured to output, as the noise source distribution, distribution of a current value as a sum of the third current in each given section on the circuit board.
